(19) United States
(12) Patent Application Publication
(10) Pub. No.: US 2020/0296823 A1
(43) Pub. Date: Sep. 17, 2020

(54) MULTI-PACKAGE ON-BOARD WAVEGUIDE INTERCONNECTS

(71) Applicant: Intel Corporation, Santa Clara, CA (US)

(72) Inventors: Telesphor Kamgaing, Chandler, AZ (US); Johanna M. Swan, Scottsdale, AZ (US); Georgios Dogiamis, Chandler, AZ (US); Henning Braunisch, Phoenix, AZ (US); Adel A. Elsherbini, Chandler, AZ (US); Aleksandar Aleksov, Chandler, AZ (US)

(73) Assignee: Intel Corporation, Santa Clara, CA (US)

(21) Appl. No.: 16/399,024

(22) Filed: Apr. 30, 2019

(30) Foreign Application Priority Data
Mar. 15, 2019 (GR) 20190100125

(51) Int. Cl. H05K 1/02; H01L 23/66; H01P 5/08

(52) U.S. Cl. CPC H05K 1/0243; H01L 2223/6627; H01P 5/08; H01L 23/66

(57) ABSTRACT

Embodiments may relate to an electronic module for use in an electronic device. The electronic module may include a printed circuit board (PCB) with a first die and a second die. A waveguide channel may be communicatively coupled with the first die and the second die and configured to convey an electromagnetic signal from the first die to the second die. In embodiments, the electromagnetic signal may have a frequency greater than 30 gigahertz (GHz). Other embodiments may be described or claimed.

### BACKGROUND

With each computing generation, the amount of data to be moved and processed on the platform increases. Data may need to be moved between various types of processors, memories, etc. for computing and storage. The increasing demand in data rate may mean denser and more complex routing schemes may be used on the motherboard to support the high-speed communication links between the different packages. One consequence of these schemes may be advanced design rules, increased layer count on the motherboard, etc., which may increase the cost of production of a product.

### BRIEF DESCRIPTION OF THE DRAWINGS

FIG. 1 depicts an example electronic module of an electronic device, in accordance with various embodiments herein.

FIG. 2 depicts an alternative example electronic module of an electronic device, in accordance with various embodiments herein.

FIG. 3 depicts an alternative example electronic module of an electronic device, in accordance with various embodiments herein.

FIG. 4 depicts an alternative example electronic module of an electronic device, in accordance with various embodiments herein.

FIG. 5 depicts an alternative example electronic module of an electronic device, in accordance with various embodiments herein.

FIG. 6 depicts an alternative example electronic module of an electronic device, in accordance with various embodiments herein.

FIG. 7 depicts an example technique for making a electronic module of an electronic device, in accordance with various embodiments herein.

FIG. 8 illustrates an example device that may use various embodiments herein, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted above, the amounts of data to be moved/processed on an electronic device platform may be increasing. The consequences of this increase may include more advanced design rules, increased layer count, etc. Embodiments herein relate to reducing the signal congestion on a circuit board by introducing high-speed signal links that occupy a smaller motherboard footprint. Specifically, the high-speed signal links may be or include one or more waveguide channels that allow for communication of electromagnetic signals in the millimeter-wave (mmWave) frequency band, which may generally be considered to be between approximately 20 gigahertz (GHz) and approximately 300 GHz. In some embodiments, the electromagnetic signals may have an even higher frequency than the mmWave-frequency band and may be, e.g., on the order of 300 GHz or above (i.e., terahertz (THz)-wave frequencies), 1 THz, or above, or higher.

More specifically, embodiments herein relate to use of a waveguide channel as an ultra-high-speed wireline communication link between two packages on a same circuit board or between two dies directly coupled to the same circuit board. The waveguide channel may operate at mmWave or THz-wave frequencies. Use of such a waveguide channel may provide a number of advantages. For example, the relatively high bandwidth density of the waveguide channel may reduce the number of traces that are to be implemented on a board or package. Additionally, use of the waveguide channel may enable socket-less communication between various chips on the same circuit board. As a result, the thickness and footprint reduction of the circuit board may be possible, which may result in cost reduction and smaller form factors of products that use embodiments herein. Additionally, direct chip attach (e.g., where the chip is directly coupled with the circuit board) may be possible in some applications such as portable or client devices.

More generally, embodiments herein may include an electronic module that includes multiple microelectronic packages on a circuit board. The electronic module or the circuit board may be, for example, considered to be a motherboard of an electronic device. In other embodiments, the electronic module or the circuit board may be, for example, considered to be an interposer or some other type of electronic module or circuit board.

In some embodiments, the microelectronic package may be or may be similar to a semiconductor package that includes one or more dies coupled with a package substrate. The dies of the microelectronic packages may have an active element (e.g., a processor, a memory, etc.) and one or more passive elements (e.g., resistors, capacitors, etc.). The semiconductor package may be coupled with the circuit board with one or more other elements (e.g., a socket, an interposer, etc.) positioned therebetween, or the semiconductor package may be directly coupled with the circuit board by some form of an interconnect. In other embodiments, the microelectronic package may not have the package substrate, and instead the die may be directly coupled with the circuit board by some form of an interconnect.

It may be desirable for two or more of the microelectronic packages to communicate at data speeds in the order of 10s to 1000s of gigabits per second (Gbps). In order to communicate at these data speeds, it may be desirable to use an on-board waveguide channel that is capable of propagating an electromagnetic wave in the mmWave-frequencies, THz-frequencies, or above.

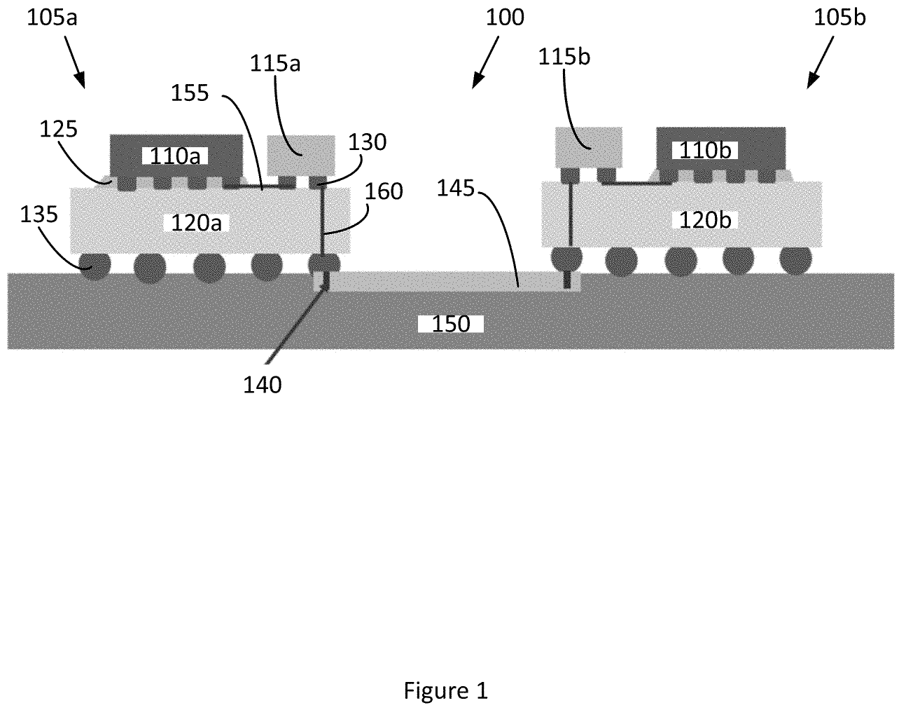

FIG. 1 depicts an example electronic module 100 of an electronic device, in accordance with various embodiments herein. It will be noted that each and every element of FIG. 1 may not be labeled for the sake of avoidance of clutter of the Figure. However, it will be understood from the picture and the below description that similar-looking elements in similar places (e.g., like the interconnects, vias, etc.) may share characteristics with one another.

The circuit board may include two microelectronic packages 105a and 105b (collectively, microelectronic packages 105). In the embodiment of FIG. 1, the microelectronic packages 105a/105b may include a package substrate 120a/120b with a die 110a/110b attached thereto. The package substrates 120a/120b may be collectively referred to herein as package substrates 120, and the dies 110a/110b may be collectively referred to herein as dies 110.

The package substrates 120 may be cored or coreless. In various embodiments, the package substrates 120 may include one or more layers of an organic or inorganic dielectric material. The dielectric material may be, for example, a build-up film made of silica-filled epoxy, or some other appropriate dielectric material. The package substrates 120 may also include one or more conductive elements such as traces, pads, vias, etc. that may route signals from one area or element of the package substrate 120 to another. Such a via may be via 160, which may communicatively couple an element at one side of the package substrate 120 with another side of the package substrate 120. It will be understood that although only a single via 160 is depicted as performing this function, in other embodiments the coupling may include a plurality of vias, traces, etc. In various embodiments, the package substrates 120 may include one or more active or passive elements either positioned within the package substrates 120, or coupled to the package substrates 120. However, these extra elements are not depicted in FIG. 1 for the sake of avoidance of clutter of the Figure.

As noted above, the dies 110a may include one or more active or passive elements. The active elements may be or include a singular or distributed processor, one or more cores of a distributed processor, a memory, etc. The processor may be, for example, a central processing unit (CPU), a graphics processing unit (GPU), or some other type of processor. The passive element may include or be a resistor, a capacitor, an inductor, etc.

The microelectronic packages 105 may also include one or more transceivers 115a/115b (collectively, transceivers 115). Generally, and as will be described in greater detail below, the transceivers 115 may be communicatively coupled with the dies 110 by one or more conductive elements such as trace 155. Specifically, the transceivers 115 may be configured to receive an electronic signal from the die 110, and then modulate, up-convert, or otherwise alter the electronic signal to a high-frequency electronic signal. The high-frequency electronic signal may have a frequency on the order of a mmWave-frequency, a THz-frequency, or higher. The transceiver 115 may then output the high-frequency electronic signal. Additionally or alternatively, a transceiver 115 may be configured to receive a high-frequency electronic signal and then de-modulate, down-convert, or otherwise alter the high-frequency electronic signal to a lower-frequency electronic signal which may then be output to a die 110.

The trace 155 may be formed of a conductive material such as copper, and configured to convey one or more electronic signals between a die 110 and a transceiver 115. Although only a single trace 155 is shown, it will be understood that in other embodiments a die 110 and a transceiver 115 may be communicatively coupled by a plurality of conductive elements such as one or more traces, vias, etc. In some embodiments the trace 155 may be positioned within the package substrate 120, rather than on top of the package substrate 120 as shown.

One or both of the dies 110 and the transceivers 115 may be coupled with the package substrate 120 by one or more interconnects such as interconnects 130. As depicted, the interconnects may be a solder ball or solder bump, and may be an element of, e.g., a ball grid array (BGA). However, in other embodiments, one or both of the dies 110 and the transceiver 115 may be coupled with the package substrate 120 by some other type of interconnect such as a socket, a mechanical coupling like a clamp, an element of a land grid array (LGA), a pin of a pin grid array (PGA), or some other type of interconnect. In some embodiments, an underfill 125 may be positioned between an element of the microelectronic packages 105 and the package substrate 120. For example, as shown, the underfill 125 may be present between a die 110 and a package substrate 120. The underfill 125 may help physically secure the die 110 to the package substrate, protect a face of the die 110, or perform some other function. In embodiments, the underfill 125 may be or include epoxy, mold compound, or some other dielectric material with a relatively low-loss tangent such as may be dictated by use of high-frequency signals. Some specific materials of the underfill 125 may be or include silica-filled epoxides, ceramic filled epoxides, silica-filled imides, alumina filled organic matrix, etc. In other embodiments, the underfill 125 may not be present.

As can be seen, the microelectronic packages 105 may be coupled with a printed circuit board (PCB) 150, for example by interconnects 135 which may be similar to, and share one or more characteristics of, interconnects 130. For example, the interconnects 135 may be elements of a BGA, PGA, LGA, they may be a socket, they may be replaced by a clamp, etc.

Similarly to the package substrate 120, the PCB 150 may be cored or coreless, and may include one or more layers of an organic or inorganic dielectric material such as build-up film, prepreg, FR4, or some other type of dielectric material. The PCB 150 may also have one or more conductive elements such as one or more traces, pads, vias, etc. either positioned on or within the PCB 150. The PCB 150 may also include one or more active or passive elements positioned within or on the PCB 150, however these extra elements may not be depicted in FIG. 1 for the sake of clarity of the Figure and lack of clutter.

The PCB 150 may include a waveguide channel 145. The waveguide channel 145 may be a dielectric waveguide, a coaxial waveguide, a rectangular waveguide, a substrate-integrated waveguide (SIW), or some other type of waveguide. Specifically, the waveguide may be configured to convey one or more high-frequency electromagnetic signals (e.g., electromagnetic signals with a frequency in the mmWave-frequency range, THz-frequency range, or above) between microelectronic packages 105a and 105b. It will be understood that although the waveguide channel 145 is depicted as being in a topmost or outer portion of the PCB 150, in some embodiments the waveguide channel 145 may be positioned within the PCB 150, e.g., between two layers of the PCB 150. Additionally, although only a single waveguide channel 145 is depicted in FIG. 1, in other embodiments the PCB 150 may include a plurality of waveguide channels that communicatively link microelectronic packages 105a and 105b, or link one of the microelectronic packages 105 with a third microelectronic package that is not pictured in FIG. 1. In embodiments where a plurality of waveguide channels links two microelectronic packages, the plurality of waveguide channels may be referred to as a “waveguide bundle.”

The waveguide channel 145 may include one or more signal launchers 140. The signal launchers 140 may be a radiative element such as an antenna, a plurality of opposing metal plates, or some other type of radiative element. The signal launchers 140 may be configured to receive a high-frequency electronic signal (e.g., from a transceiver such as transceiver 115) and convert the high-frequency electronic signal supported by package substrate 120 to a high-frequency electromagnetic signal supported by the waveguide 145 (or vice-versa). The signal launcher 140 may then output the high-frequency electromagnetic signal to the waveguide channel 145 so that the high-frequency electromagnetic signal may propagate through the waveguide channel 145.

Generally, in operation, the electronic module 100 may operate as follows. The die 110a of microelectronic package 105a may generate an electronic signal that is transferred through trace 155 to transceiver 115a. Transceiver 115a may modulate, up-convert, or otherwise alter the signal to a high-frequency electronic signal as described above, and output that high-frequency electronic signal. Specifically, in FIG. 1, the high-frequency electronic signal may be output through one of interconnects 130 to package substrate 120a, and more specifically to via 160 of package substrate 120a. The high-frequency electronic signal may propagate along the via 160, through an interconnect 135, and to signal launcher 140. Signal launcher 140 may convert the high-frequency electronic signal to a high-frequency electromagnetic signal as described above, which then propagates through waveguide channel 145. A corresponding signal launcher may receive the high-frequency electromagnetic signal and convert it to a high-frequency electronic signal which is output to microelectronic package 105b, and more specifically to package substrate 120b. The high-frequency electronic signal propagates to transceiver 115b where it is down-converted, demodulated, or otherwise altered to an electronic signal which is then provided to die 110b.

It will be understood that the above-described signal path is only intended as one example of such a signal path, and other embodiments may have other signal paths. Additionally, although the signal path is only described as unidirectional, in other embodiments the signal path may additionally or alternatively propagate from microelectronic package 105b to microelectronic package 105a. It will further be understood that various elements of a single microelectronic package (e.g., interconnects 130) which are depicted as similar to one another may vary in some embodiments. For example, the interconnects coupling the die 110 to the package substrate 120 may be different than the interconnects coupling the transceiver 115 to the package substrate 120. Various elements between packages may likewise differ. For example, die 110a may be of a different type than die 110b. Finally, in some embodiments the transceiver 115 and the die 110a may not be elements of the same microelectronic package, but rather they may be elements of separate microelectronic packages that are communicatively coupled with one another. Other elements may vary in other embodiments.

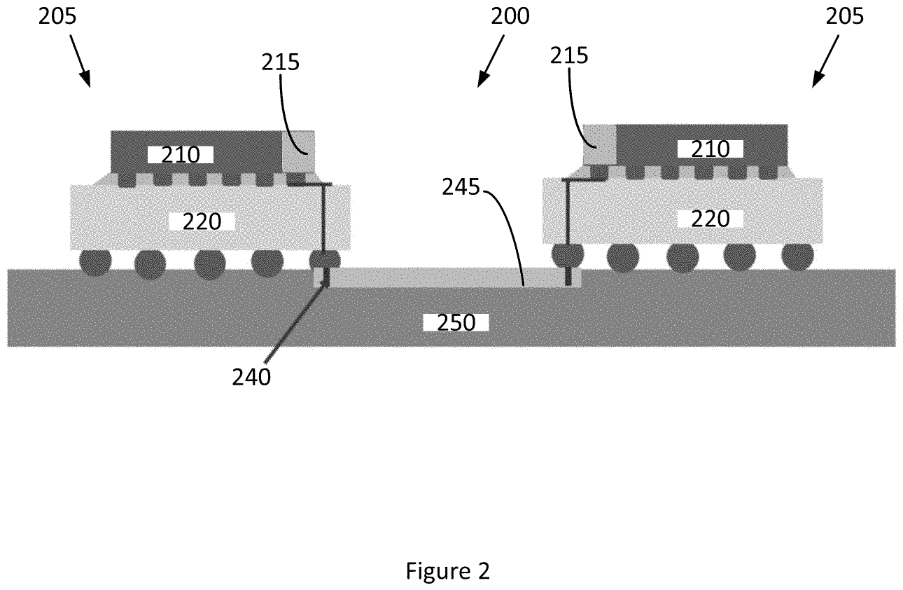

FIG. 2 depicts an alternative example electronic module 200 of an electronic device, in accordance with various embodiments herein. The electronic module 200 may include microelectronic packages 205, which may be respectively similar to, and share one or more characteristics of, microelectronic packages 105. Specifically, the microelectronic packages may include a package substrate 220, which may be similar to, and share one or more characteristics of, package substrates 120. The microelectronic packages 205 may be coupled with a PCB 250 that includes a waveguide channel 245 with one or more signal launchers 240, which may be respectively similar to, and share one or more characteristics of, PCB 150, waveguide channel 145, and signal launchers 140.

The microelectronic packages 205 may include a die 210 and a transceiver 215, which may be similar to, and share one or more characteristics of, die 110 and transceiver 115. However, as can be seen in FIG. 2, the die 210 and transceiver 215 may be a unitary chip. That is, in embodiments, the transceiver 215 may be an element of the die 210. For example, the transceiver may be a logic, circuit, or some other element that is either integrated on or within the die 210.

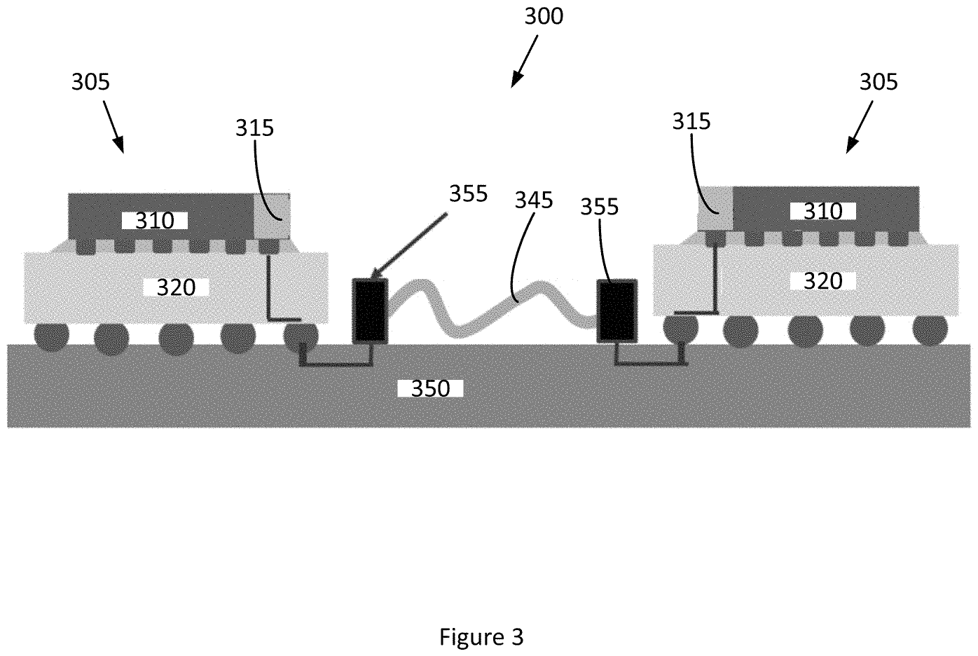

FIG. 3 depicts an alternative example electronic module 300 of an electronic device, in accordance with various embodiments herein. The electronic module 300 may include microelectronic packages 305 with dies 310, transceivers 315, and package substrates 320, which may be respectively similar to, and share one or more characteristics of, microelectronic packages 205, dies 210, transceivers 215, and package substrates 220. The electronic module 300 may also include a PCB 350, which may be similar to, and share one or more characteristics of, PCB 250.

The electronic module 300 may also include a waveguide channel 345 and one or more waveguide connectors 355. The waveguide channel 345, as pictured, may be a flexible waveguide such as a dielectric waveguide. However, in other embodiments the waveguide channel 345 may be a different type of waveguide such as a coaxial cable.

The connectors 355 may be coupled to the PCB 350, and the waveguide channel 345 may be positioned therebetween. As can be seen, the connectors 355 may be communicatively coupled with the microelectronic packages 305. The connectors 355 may include a signal launcher similar to signal launchers 140 or 240, and be configured to receive a high-frequency electronic signal from a microelectronic package 305, convert it to a high-frequency electromagnetic signal, and launch the high-frequency electromagnetic signal into waveguide channel 345. Additionally or alternatively, one of the connectors 355 may be configured to receive a high-frequency electromagnetic signal from waveguide channel 345, convert it to a high-frequency electronic signal, and output the high-frequency electronic signal to a microelectronic package 305. It will be noted that although the connectors 355 are depicted as coupled with the PCB 350, in other embodiments the connectors 355 may be elements of, or other connected with, the package substrates 320 or the transceivers 315.

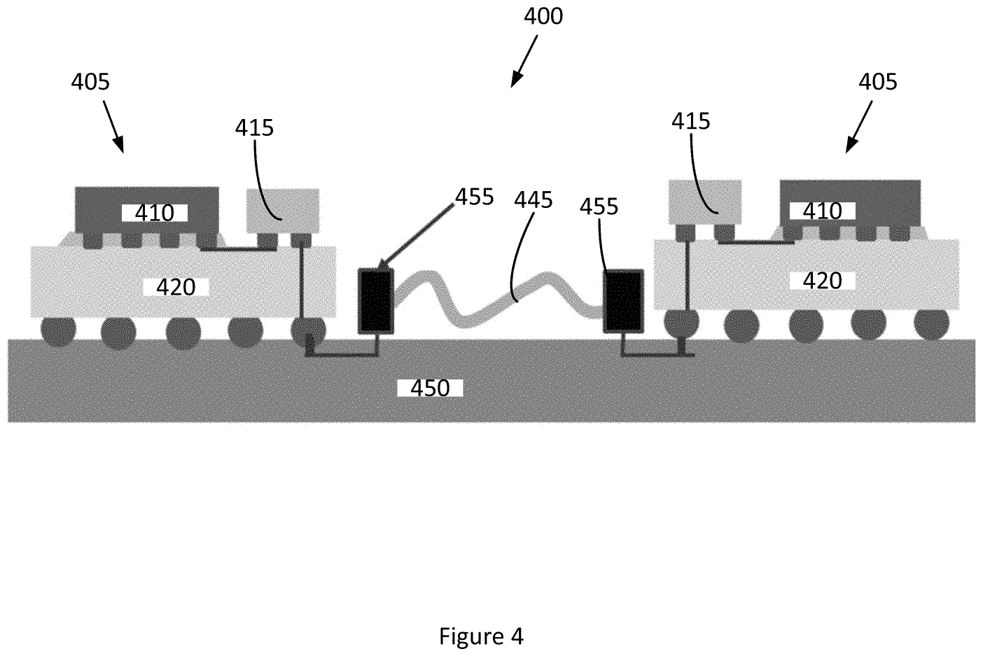

FIG. 4 depicts an alternative example electronic module 400 of an electronic device, in accordance with various embodiments herein. In this embodiment, the electronic module 400 may include microelectronic packages 405 with dies 410, transceivers 415, and package substrates 420, which may be respectively similar to, and share one or more characteristics of, microelectronic packages 105, dies 110, transceivers 115, and package substrates 120.

The electronic module 400 may also include a PCB 450 with connectors 455 and a waveguide channel 445, which may be respectively similar to, and share one or more characteristics of, PCB 350, connectors 355, and waveguide channel 345.

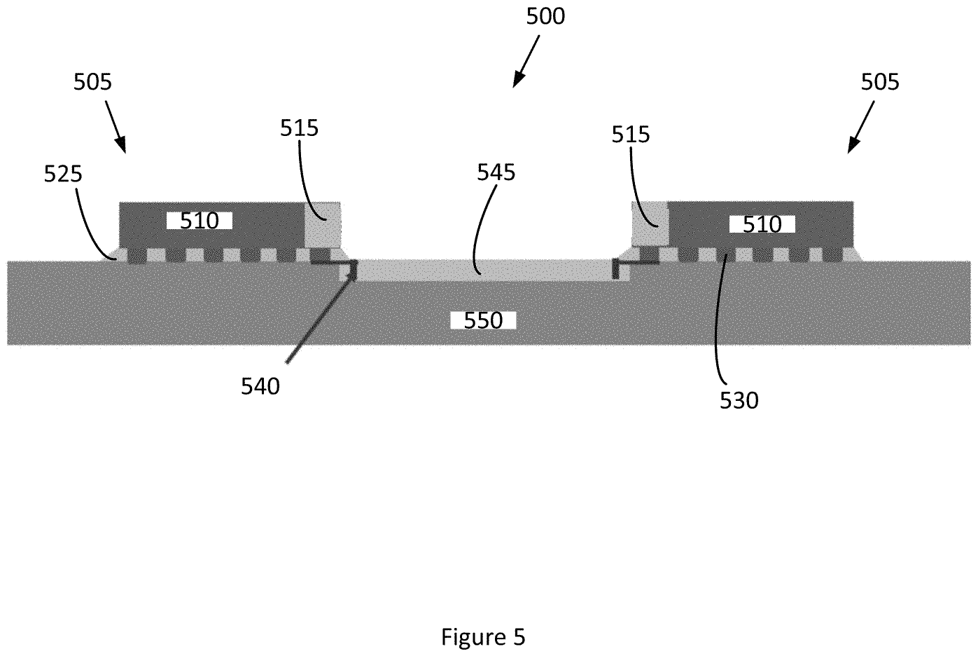

FIG. 5 depicts an alternative example electronic module 500 of an electronic device, in accordance with various embodiments herein. Generally, the high bandwidth density of the waveguide channel may result in a significant reduction of the die bumps required for high-speed signaling. This reduction may lead to the relaxation of the first level interconnect (FLI) bump pitch, which in turn may translate into the ability to implement multi-chip modules (MCM) with direct chip attach (DCA) to the substrate. This implementation may be used, for example, in the client or portable device space. An example of this implementation is depicted in FIG. 5 with respect to electronic module 500.

The electronic module 500 may include a PCB 550 with a waveguide channel 545 and signal launchers 540, which may be respectively similar to, and share one or more characteristics of, PCB 150, waveguide channel 145, and signal launchers 140.

The electronic module 500 may include microelectronic packages 505, which may be generally similar to, and share one or more characteristics of, microelectronic packages 205. However, as can be seen in FIG. 5, the microelectronic packages 505 may general comprise a die 510 and a transceiver 515 which may be directly coupled with the PCB 550. The die 510 may be similar to, and share one or more characteristics of, die 210. Similarly, transceiver 515 may be similar to, and share one or more characteristics of, transceiver 215.

Specifically, as can be seen in FIG. 5, the die 510 and transceiver 515 may be coupled with the substrate by interconnects 530 which may be similar to, and share one or more characteristics of, interconnects 130. Also, as can be seen in FIG. 5, the electronic module 500 may include an underfill 525 which may be similar to, and share one or more characteristics of, underfill 125. It will be noted that although the die 510 and transceiver 515 are depicted as unitary, in some embodiments the die 510 may be physically separated from transceiver 515 in a fashion similar to die 110 and transceiver 115.

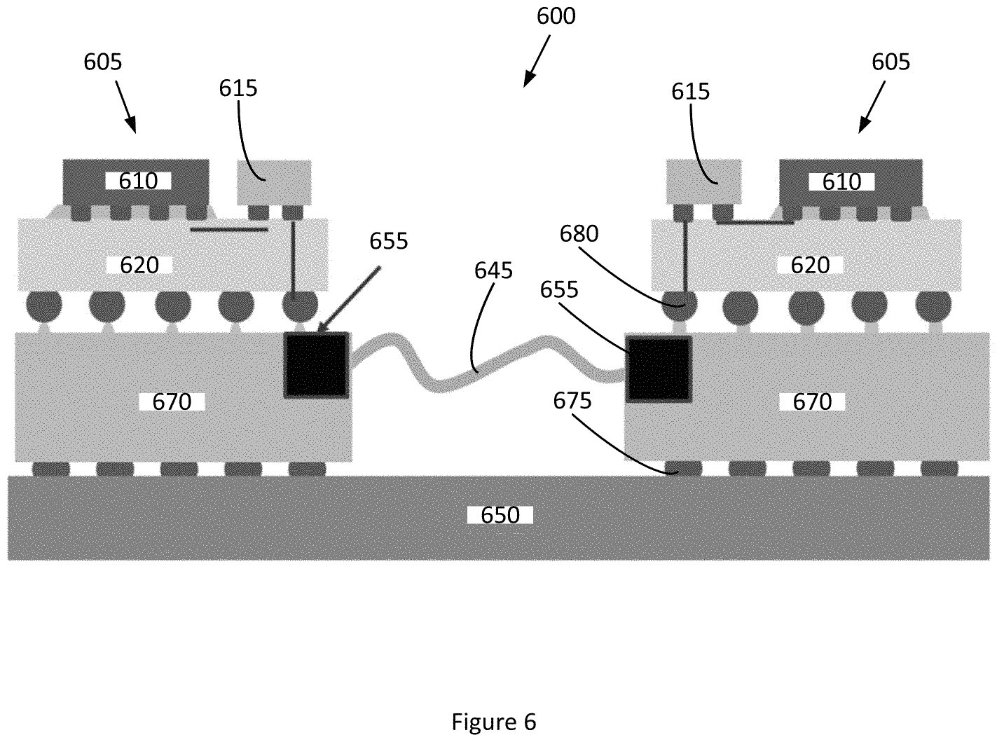

FIG. 6 depicts an alternative example electronic module 600 of an electronic device, in accordance with various embodiments herein. As previously noted, in some embodiments the microelectronic package may be coupled with the substrate by a socket. Generally, the socket may keep the microelectronic package and a waveguide connector stable within the socket. FIG. 6 depicts an example electronic module 600 with such a socket.

Generally, the electronic module 600 may include microelectronic packages 605 with dies 610, transceivers 615, and package substrates 620, which may be respectively similar to, and share one or more characteristics with, microelectronic packages 105, dies 110, transceivers 115, and package substrates 120. The electronic module 600 may also have a PCB 650, which may be similar to, and share one or more characteristics of, PCB 350.

The electronic module 600 may also include one or more sockets 670. The sockets 670 may generally be positioned between the microelectronic packages 605 and the PCB 650. The sockets 670 may be coupled with the PCB 650, for example by interconnects 675. Interconnects 675 may be similar to, and share one or more characteristics with, interconnects 135. The sockets 670 may also couple with the microelectronic packages by interconnects 680, which may also be similar to, and share one or more characteristics with, interconnects 135. Specifically, in some embodiments the sockets 670 may include one or more elements of a BGA, a PGA, an LGA, etc. In some embodiments, the socket may extend partially up the side of the microelectronic packages 605 and hold the microelectronic packages 605 in place. In some embodiments, the sockets 670 may include one or more elements that go over the top of the microelectronic packages 605 (as oriented in FIG. 6) and hold the microelectronic packages 605 in place with a “clamp” type mechanism.

In some embodiments, the sockets 670 may include a connector 655, which may be similar to, and share one or more characteristics with, connectors 455. As shown, the connectors 655 may be elements of the socket 670, however in other embodiments the connectors 655 may be external to, but physically or communicatively coupled with, sockets 670. The connectors 655 may be coupled with a waveguide 645, which may be similar to, and share one or more characteristics with, waveguide 445.

It will be understood that the above-described embodiments of FIGS. 1-6 are intended as examples of various embodiments, and depict various configurations of certain elements. However, in other embodiments certain elements may be in a different configuration. For example, in some embodiments the transceiver may be located within the package substrate, the socket, positioned on the socket, or positioned at a different side of the package substrate than depicted in various Figures. In some embodiments, the various signal launchers may be located on the die, package substrate, socket, etc. Additionally, it will be understood that although each and every element of FIGS. 2-6 may not be specifically addressed, certain elements that appear similar to elements of FIG. 1 may generally be understood to be similar to the elements of FIG. 1 (e.g., the interconnects, the underfill, etc.).

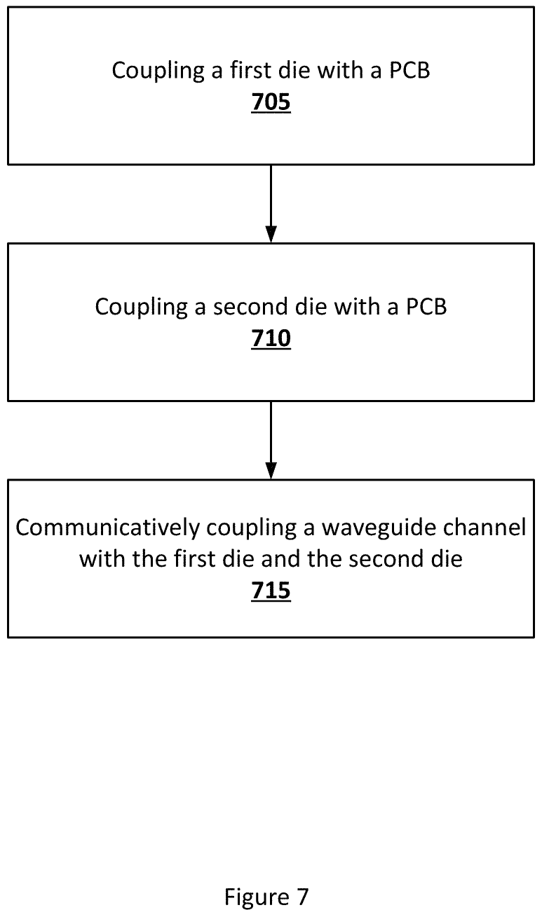

FIG. 7 depicts an example technique for making an electronic module, in accordance with various embodiments herein. Generally, the technique may be described with respect to electronic module 100, however it will be understood that the described technique may apply to some other circuit board described herein, or related to embodiments herein, with or without adaptation of the technique.

Generally, the technique may involve coupling, at 705, a first die with a PCB. The die may be similar to, for example, die 110, and the PCB may be similar to, for example, PCB 150. In the embodiment of FIG. 1, the die may be coupled with the PCB as an element of a microelectronic package that is coupled with the PCB. However, in other embodiments the die may be similar to, for example, die 510 which is coupled directly with the PCB, or the die may be coupled to the PCB by a socket such as socket 670.

The technique may then involve coupling, at 710, a second die with the PCB. Similarly to the first die described above with respect to element 705, the second die may either be coupled directly to the PCB, may be coupled to the PCB as an element of a microelectronic package, a socket may be used, etc.

The technique may then include communicatively coupling, at 715, a waveguide channel with the first die and the second die. The waveguide channel may be similar to, for example, waveguide channel 145 or some other waveguide channel discussed herein.

It will be understood that the above-described technique is only one example technique, and other embodiments may have techniques with more or fewer elements. In some embodiments certain elements, e.g. elements 705 and 710, may occur concurrently with one another, or in a different order.

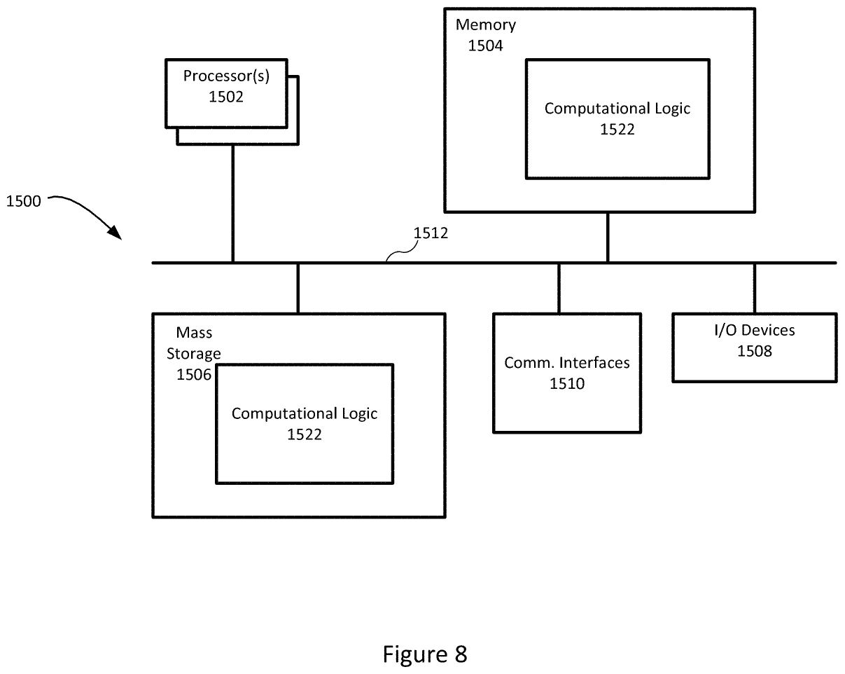

FIG. 8 illustrates an example computing device 1500 suitable for use with various of the electronic modules such as electronic module 100, 200, 300, 400, 500, or 600 (collectively, “electronic modules 100-600”), in accordance with various embodiments. Specifically, in some embodiments, the computing device 1500 may include one or more of electronic modules 100-600 therein.

As shown, computing device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a CPU, a microprocessor, and the like. The processor 1502 may be implemented as an integrated circuit having multi-cores, e.g., a multi-core microprocessor. The computing device 1500 may include mass storage devices 1506 (such as diskette, hard drive, volatile memory (e.g., DRAM, compact disc read-only memory (CD-ROM), digital versatile disk (DVD), and so forth)). In general, system memory 1504 and/or mass storage devices 1506 may be temporal and/or persistent storage of any type, including, but not limited to, volatile and non-volatile memory, optical, magnetic, and/or solid state mass storage, and so forth. Volatile memory may include, but is not limited to, static and/or DRAM. Non-volatile memory may include, but is not limited to, electrically erasable programmable read-only memory, phase change memory, resistive memory, and so forth. In some embodiments, one or both of the system memory 1504 or the mass storage device 1506 may include computational logic 1522, which may be configured to implement or perform, in whole or in part, one or more instructions that may be stored in the system memory 1504 or the mass storage device 1506. In other embodiments, the computational logic 1522 may be configured to perform a memory-related command such as a read or write command on the system memory 1504 or the mass storage device 1506.

The computing device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth).

The communication interfaces 1510 may include communication chips (not shown) that may be configured to operate the device 1500 in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments.

The computing device 1500 may further include or be coupled with a power supply. The power supply may, for example, be a power supply that is internal to the computing device 1500 such as a battery. In other embodiments the power supply may be external to the computing device 1500. For example, the power supply may be an electrical source such as an electrical outlet, an external battery, or some other type of power supply. The power supply may be, for example alternating current (AC), direct current (DC) or some other type of power supply. The power supply may in some embodiments include one or more additional components such as an AC to DC convertor, one or more downconverters, one or more upconverters, transistors, resistors, capacitors, etc. that may be used, for example, to tune or alter the current or voltage of the power supply from one level to another level. In some embodiments the power supply may be configured to provide power to the computing device 1500 or one or more discrete components of the computing device 1500 such as the processor(s) 1502, mass storage 1506, I/O devices 1508, etc.

The above-described computing device 1500 elements may be coupled to each other via system bus 1512, which may represent one or more buses. In the case of multiple buses, they may be bridged by one or more bus bridges (not shown). Each of these elements may perform its conventional functions known in the art. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various computing devices.

The number, capability, and/or capacity of the elements 1508, 1510, 1512 may vary, depending on whether computing device 1500 is used as a stationary computing device, such as a set-top box or desktop computer, or a mobile computing device, such as a tablet computing device, laptop computer, game console, or smartphone. Their constitutions are otherwise known, and accordingly will not be further described.

In various implementations, the computing device 1500 may comprise one or more components of a data center, a laptop, a netbook, a notebook, an ultrabook, a smartphone, a tablet, a personal digital assistant (PDA), an ultra mobile PC, a mobile phone, or a digital camera. In further implementations, the computing device 1500 may be any other electronic device that processes data.

In some embodiments, as noted above, computing device 1500 may include one or more of electronic modules 100-600. For example, in some embodiments the processor 1502, memory 1504, or some other component of the computing device 1500 may be one of the various dies 110, 210, 310, etc.

### EXAMPLES OF VARIOUS EMBODIMENTS

Example 1 includes a electronic module for use in an electronic device, the electronic module comprising: a printed circuit board (PCB); a first die coupled with the PCB; a second die coupled with the PCB; and a waveguide channel communicatively coupled with the first die and the second die, wherein the waveguide channel is to convey an electromagnetic signal from the first die to the second die, and wherein the electromagnetic signal has a frequency greater than 30 gigahertz (GHz).

Example 2 includes the electronic module of example 1, wherein the electromagnetic signal has a frequency greater than 300 GHz.

Example 3 includes the electronic module of example 1, wherein the PCB comprises a plurality of layers, and wherein the waveguide channel is an element of a layer of the plurality of layers of the PCB.

Example 4 includes the electronic module of example 1, wherein the waveguide channel includes a waveguide connector that is coupled with the PCB.

Example 5 includes the electronic module of any of examples 1-4, wherein the first die is an element of a microelectronic package that further includes a high-frequency transceiver that is to up-convert an electronic signal from a logic component of the first die to an electronic signal with a frequency greater than 30 GHz.

Example 6 includes the electronic module of example 5, wherein the high-frequency transceiver is an element of the first die.

Example 7 includes the electronic module of example 5, wherein the high-frequency transceiver is communicatively coupled with the first die.

Example 8 includes the electronic module of example 5, wherein the microelectronic package includes a package substrate physically coupled with the first die and the PCB.

Example 9 includes the electronic module of example 5, wherein the PCB further includes a signal launcher that is to convert the electronic signal with the frequency greater than 30 GHz to the electromagnetic signal.

Example 10 includes the electronic module of any of examples 1-4, wherein the waveguide channel is physically coupled with a socket that communicatively or physically couples the first die with the PCB.

Example 11 includes the electronic module of any of examples 1-4, wherein the first die is directly coupled with the PCB.

Example 12 includes a method of forming an electronic module for use in an electronic device, wherein the method comprises: coupling a first die with a printed circuit board (PCB); coupling a second die with the PCB; and communicatively coupling a waveguide channel with the first die and the second die, wherein the waveguide channel is to convey an electromagnetic signal with a frequency greater than 30 gigahertz (GHz) between the first die and the second die.

Example 13 includes the method of example 12, wherein the electromagnetic signal has a frequency greater than 300 GHz.

Example 14 includes the method of examples 12 or 13, wherein coupling the first die with the PCB includes coupling a microelectronic package to the PCB, wherein the microelectronic package includes a package substrate, the first die, and a high-frequency transceiver element that is to receive an electronic signal from a logic of the first die and up-convert the electronic signal to an electronic signal with a frequency greater than 30 GHz.

Example 15 includes the method of examples 12 or 13, wherein the waveguide channel is an element of a layer of the PCB and communicatively coupling the waveguide channel with the first die includes communicatively coupling the first die with a signal launcher of the PCB, wherein the signal launcher is to receive an electronic signal related to a signal generated by the first die and convert the electronic signal to the electromagnetic signal.

Example 16 includes the method of examples 12 or 13, further comprising coupling the waveguide channel to the PCB.

Example 17 includes an electronic device comprising: a memory; and a motherboard coupled with the memory, wherein the motherboard includes: a first computing component coupled with the motherboard, wherein the first computing component includes a first die and a first transceiver, wherein the first transceiver is to: receive a first electronic signal from the first die; and up-convert the first electronic signal to a second electronic signal with a frequency greater than 30 gigahertz (GHz); a waveguide channel that is communicatively coupled with the first transceiver, wherein the waveguide channel is to receive and convey an electromagnetic signal with a frequency greater than 30 GHz, wherein the electromagnetic signal is based on the second electronic signal; and a second computing component coupled with the motherboard, wherein the second computing component includes a second die and a second transceiver, wherein the second transceiver is to: receive a third electronic signal that is related to the electromagnetic signal, wherein the third electronic signal has a frequency greater than 30 GHz; down-convert the third electronic signal to a fourth electronic signal; and provide the fourth electronic signal to the second die.

Example 18 includes the electronic device of example 17, wherein the second electronic signal has a frequency greater than 300 GHz.

Example 19 includes the electronic device of examples 17 or 18, wherein the second transceiver is an element of the second die.

Example 20 includes the electronic device of examples 17 or 18, wherein the second computing component is a microelectronic package that includes a package substrate physically coupled with the motherboard, the second die, and the second transceiver.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. An electronic module for use in an electronic device, the electronic module comprising:
a printed circuit board (PCB);
a first die coupled with the PCB;
a second die coupled with the PCB; and
a waveguide channel communicatively coupled with the first die and the second die, wherein the waveguide channel is to convey an electromagnetic signal from the first die to the second die, and wherein the electromagnetic signal has a frequency greater than 30 gigahertz (GHz).

2. The electronic module of claim 1, wherein the electromagnetic signal has a frequency greater than 300 GHz.

3. The electronic module of claim 1, wherein the PCB comprises a plurality of layers, and wherein the waveguide channel is an element of a layer of the plurality of layers of the PCB.

4. The electronic module of claim 1, wherein the waveguide channel includes a waveguide connector that is coupled with the PCB.

5. The electronic module of claim 1, wherein the first die is an element of a microelectronic package that further includes a high-frequency transceiver that is to up-convert an electronic signal from a logic component of the first die to an electronic signal with a frequency greater than 30 GHz.

6. The electronic module of claim 5, wherein the high-frequency transceiver is an element of the first die.

7. The electronic module of claim 5, wherein the high-frequency transceiver is communicatively coupled with the first die.

8. The electronic module of claim 5, wherein the microelectronic package includes a package substrate physically coupled with the first die and the PCB.

9. The electronic module of claim 5, wherein the PCB further includes a signal launcher that is to convert the electronic signal with the frequency greater than 30 GHz to the electromagnetic signal.

10. The electronic module of claim 1, wherein the waveguide channel is physically coupled with a socket that communicatively or physically couples the first die with the PCB.

11. The electronic module of claim 1, wherein the first die is directly coupled with the PCB.

12. A method of forming an electronic module for use in an electronic device, wherein the method comprises:
coupling a first die with a printed circuit board (PCB);
coupling a second die with the PCB; and
communicatively coupling a waveguide channel with the first die and the second die, wherein the waveguide channel is to convey an electromagnetic signal with a frequency greater than 30 gigahertz (GHz) between the first die and the second die.

13. The method of claim 12, wherein the electromagnetic signal has a frequency greater than 300 GHz.

14. The method of claim 12, wherein coupling the first die with the PCB includes coupling a microelectronic package to the PCB, wherein the microelectronic package includes a package substrate, the first die, and a high-frequency transceiver element that is to receive an electronic signal from a logic of the first die and up-convert the electronic signal to an electronic signal with a frequency greater than 30 GHz.

15. The method of claim 12, wherein the waveguide channel is an element of a layer of the PCB and communicatively coupling the waveguide channel with the first die includes communicatively coupling the first die with a signal launcher of the PCB, wherein the signal launcher is to receive an electronic signal related to a signal generated by the first die and convert the electronic signal to the electromagnetic signal.

16. The method of claim 12, further comprising coupling the waveguide channel to the PCB.

17. An electronic device comprising:
a memory; and
a motherboard coupled with the memory, wherein the motherboard includes:
a first computing component coupled with the motherboard, wherein the first computing component includes a first die and a first transceiver, wherein the first transceiver is to:
receive a first electronic signal from the first die; and
up-convert the first electronic signal to a second electronic signal with a frequency greater than 30 gigahertz (GHz);
a waveguide channel that is communicatively coupled with the first transceiver, wherein the waveguide channel is to receive and convey an electromagnetic signal with a frequency greater than 30 GHz, wherein the electromagnetic signal is based on the second electronic signal; and
a second computing component coupled with the motherboard, wherein the second computing component includes a second die and a second transceiver, wherein the second transceiver is to:
receive a third electronic signal that is related to the electromagnetic signal, wherein the third electronic signal has a frequency greater than 30 GHz;
down-convert the third electronic signal to a fourth electronic signal; and
provide the fourth electronic signal to the second die.

18. The electronic device of claim 17, wherein the second electronic signal has a frequency greater than 300 GHz.

19. The electronic device of claim 17, wherein the second transceiver is an element of the second die.

20. The electronic device of claim 17, wherein the second computing component is a microelectronic package that includes a package substrate physically coupled with the motherboard, the second die, and the second transceiver.
